(19) United States
(12) Patent Application Publication
(10) Pub. No.: US 2024/0071450 A1
(43) Pub. Date: Feb. 29, 2024

(54) DEVICE FOR MODIFYING THE DIRECTION OF MAGNETIZATION OF A MAGNETIC LAYER, ASSOCIATED METHOD AND SPINTRONIC SYSTEM

(71) Applicants: Commissariat à l'énergie atomique et aux énergies alternatives, Paris (FR); THALES, Courbevoie (FR); Centre national de la recherche scientifique, Paris (FR); UNIVERSITE GRENOBLE ALPES, Saint Martin d'Heres (FR)

(72) Inventors: Jean-Philippe ATTANE, Grenoble (FR); Laurent VILA, Grenoble Cedex 09 (FR); Manuel BIBES, Palaiseau (FR)

(73) Assignees: Commissariat à l'énergie atomique et aux énergies alternatives, Paris (FR); THALES, Courbevoie (FR); Centre national de la recherche scientifique, Paris (FR); UNIVERSITE GRENOBLE ALPES, Saint Martin d'Heres (FR)

(21) Appl. No.: 18/257,161

(22) PCT Filed: Dec. 16, 2021
(86) PCT No.: PCT/EP2021/086134

§ 371 Date: Jun. 13, 2023

(30) Foreign Application Priority Data
Dec. 18, 2020 (FR) FR2013673

(51) Int. Cl. G11C 11/16; G11C 19/08; H10B 61/00; H10N 50/80; H10N 52/00

(52) U.S. Cl. CPC G11C 11/161; G11C 11/1673; G11C 19/0808; H10B 61/00; H10N 50/80; H10N 52/00

(57) ABSTRACT

A device for modifying at least the direction of magnetization of a magnetic layer, the modifying device including a ferroelectric layer having a ferroelectric polarization, arranged on or under the magnetic layer so as to define a stack including at least the magnetic layer and the ferroelectric layer, a generator apt to inject an electric current into the stack along a direction parallel to the plane of the layers of the stack, and a modification unit apt to modify the ferroelectric polarization of the ferroelectric layer, for modifying, with the generator, the direction of magnetization of the magnetic layer.

The present invention relates to a device for modifying at least the direction of magnetization of a magnetic layer. The present invention further relates to a spintronic system comprising such a device and to a modification method.

Spintronic devices build on the degree of freedom of the spin of the electron, for providing additional functions, such as non-volatility of information, to conventional electronic devices based on the charge of the electron. The term spin electronics or spintronics is used for referring to such technology.

The application of a spin-polarized current in a ferromagnetic or ferrimagnetic element can be used for manipulating the direction of magnetization of the element. The spin-polarized current generates a so-called spin transfer torque acting on the magnetization, which was used e.g. for the operation of spintronic technologies such as magnetic random access memory, based on spin transfer through a tunnel junction. In such memories, the current is applied perpendicular to the plane of a magnetic tunnel junction, which makes it possible to switch the magnetization of one of the layers composing the junction.

Another way to switch magnetization by current application is based on so-called spin-orbit torques. Such torques appear in bilayers made of a spin Hall effect material, typically a heavy metal (such as Pt, Pd, W, Ta), in contact with a ferromagnetic or ferrimagnetic material (such as Co or CoFeB). Same can also appear through the Rashba-Edelstein effect at the interface between the ferromagnetic or ferrimagnetic element and the ferroelectric element. The spin Hall effect and/or the Rashba-Edelstein effect convert a charging current flowing, this time, in the plane of a stack, into a spin current perpendicular to the plane of the stack. The spin current can initiate the oscillation and/or the reversal of magnetization of the magnetized layer.

Such technique of modifying the orientation of magnetization by spin-orbit torque is e.g. used for creating random access magnetic memories based on spin-orbit torques, wherein the information encoded in the state of magnetization of the ferromagnetic or ferrimagnetic element can be switched by applying a current in the plane of the layers. Such technique can also be used to create shift register devices, consisting of tracks wherein information is encoded via magnetic inhomogeneities, such as magnetic walls or skyrmions, which can be moved by spin-orbit torque. Such technique can also be used in spin-orbit oscillators, wherein the spin current generated by an in-plane charging current is used for sustaining magnetization oscillations, so as to generate radio frequency signals.

The fundamental element of such devices based on the spin-orbit torque is often a layer of spin Hall effect material in contact with the ferromagnetic or ferrimagnetic element. A charging current in the plane of the stack is converted into a spin current by the spin Hall effect. Such conversion between charging current and spin current is determined by the nature of the layer stack. The modification of the direction of magnetization is thus controlled solely by the current flowing in the plane of the stack.

There is thus a need for a device for modifying at least one magnetic property of a magnetic layer, which would provide more degrees of freedom for a spintronic system which would comprise such a modifying device.

For this purpose, the present description relates to a device for modifying at least the direction of magnetization of a magnetic layer, the modifying device comprising a ferroelectric layer exhibiting ferroelectric polarization, placed on or under the magnetic layer so as to define a stack comprising at least the magnetic layer and the ferroelectric layer, a generator capable of injecting an electric current into the stack in a direction parallel to the plane of the layers of the stack, and a modification unit adapted to modify the ferroelectric polarization of the ferroelectric layer to enable the generator to modify the direction of magnetization of the magnetic layer.

Thus, a means for modifying the direction of magnetization is proposed wherein this modification depends both on a current flowing in the plane of the stack, and, in a non-volatile way, on the polarization of a ferroelectric layer, in particular by applying a voltage to said ferroelectric layer. Indeed, the device uses a ferroelectric layer, the polarization state of which can be used for modifying the spin-orbit torque.

Such additional degree of freedom could be used for adding functions to such devices, such as logic functions in addition to memory, or further re-programmability.

According to other particular embodiments, the modifying device has one or a plurality of the following features, taken individually or according to all technically possible combinations:
the unit for modifying the ferroelectric polarization is a voltage source.
the magnetic layer is in contact with the ferroelectric layer.
at least one layer amongst the magnetic layer and the ferroelectric layer is nanostructured.
the stack includes an intermediate layer interposed between the ferroelectric layer and the magnetic layer, the intermediate layer including a spin Hall effect material, in particular a metal such as platinum or tungsten.
the stack includes an intermediate layer interposed between the ferroelectric layer and the magnetic layer, the intermediate layer advantageously including a material chosen from the following list, taken alone or in combination: a Weyl semi-metal, a two-dimensional material, in particular graphene, a transition-metal dichalcogenide, and a topological insulator.
the ferroelectric layer is in contact with a protective layer.
the protective layer protects a two-dimensional electron gas which forms on the surface of the ferroelectric layer.
the protective layer is obtained by depositing at least 80% of a reducing metallic element from the columns 3d, 4d, 5d, 4f, 5f of the periodic table or a combination of said elements.

The description further describes a spintronic system comprising a magnetic layer, a device for modifying at least the direction of magnetization of the magnetic layer, the modifying device being as described above, and a unit for reading the magnetization of the magnetic layer, the reading unit being e.g. a magnetic tunnel junction.

According to a particular embodiment, the spintronic system is chosen amongst a memory, a shift register, an oscillator, a part of a logic or neuromorphic device, and a radio frequency transmitter or receiver.

More particularly, the spintronic system is a shift register based on the propagation of walls of magnetic domains or of skyrmions.

In a variant, the spintronic system is a part of a logic or neuromorphic device based on the propagation of magnetic domain walls or of skyrmions or of spin waves.

The description further relates to a method for modifying at least the direction of magnetization of a magnetic layer, the method including a step of modifying the magnetization of the magnetic layer through the modification of the ferroelectric polarization of a ferroelectric layer arranged on or under the magnetic layer, so as to define a stack including at least the magnetic layer and the ferroelectric layer, and through the injection of an electric current into the stack along a direction parallel to the plane of the layers of the stack.

According to a particular embodiment, the modification of the ferroelectric polarization is implemented by applying an electric voltage to the ferroelectric layer.

Other features and advantages of the invention will appear upon reading hereinafter the description of the embodiments of the invention, given only as an example, and making reference to the following drawings:

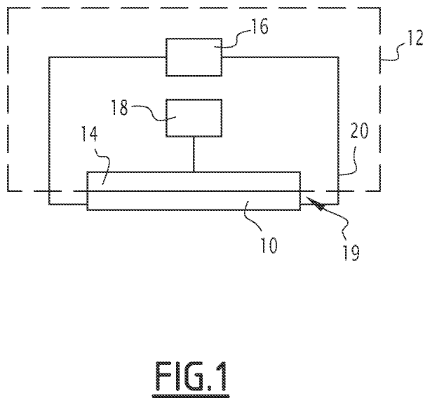

FIG. 1, a schematic representation of a magnetic layer and an example of a device for modifying at least one magnetic property of the magnetic layer,

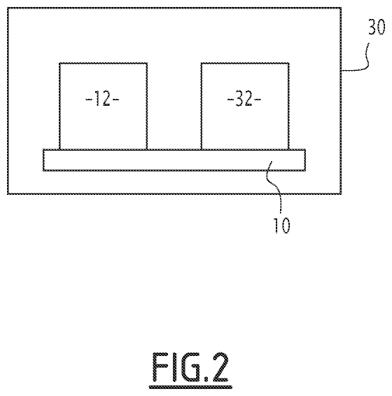

FIG. 2 is a schematic representation of an example of spintronic system,

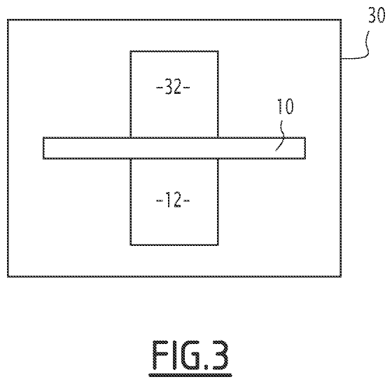

FIG. 3, a schematic representation of another example of spintronic system, and

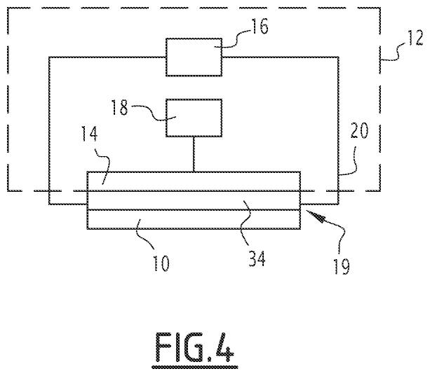

FIG. 4, a schematic representation of the magnetic layer and another example of a device for modifying at least one magnetic property of the magnetic layer.

Since the present invention is based on a new technique for modifying a magnetic property of a magnetic layer, it is first presented how to physically implement such a technique by describing a specific modifying device before explaining how such a modifying device can be used for obtaining a spintronic system which provides more functions by means of the degrees of freedom obtained by the new technique.

FIG. 1 thus shows a physical implementation of the aforementioned new technique. More specifically, a magnetic layer 10 and a modifying device 12 are shown in FIG. 1.

By definition, the magnetic layer 10 is a ferromagnetic and/or ferrimagnetic single-layer or multi-layer. In other words, the material or all the materials forming the single-layer or the multi-layer form a ferromagnetic and/or ferrimagnetic assembly even if some of the materials contained in the composition of said layer are intrinsically non-ferromagnetic and/or non-ferrimagnetic.

According to a first example, the magnetic element of the spin polarizing single or multi-layer is a Heusler alloy, e.g. Cu₂MnAl, Cu₂MnIn, Cu₂MnSn, NfiMnAl, NfiMnIn, NfiMnSn, NfiMnSb, Ni₂MnGa Co₂MnAl, Co₂MnSi, Co₂MnGa, Co₂MnGe, Pd₂MnAl, Pd₂MnIn, Pd₂MnSn, Pd₂MnSb, Co₂FeSi, Co₂FeAl, Fe₂VAl, Mn₂VGa, Co₂FeGe, MnGa, or MnGaRu.

In a second example, the ferromagnetic and/or ferrimagnetic material is based on 3d elements such as Fe, Ni, Cr, Mn, Co, used pure or in the form of multilayers or alloys, with each other or with other elements, such as CoPtCr, CoFe, CoFeB, CoNi, NiFe, FePt or FePd.

In a third example, the ferromagnetic and/or ferrimagnetic material can include rare earth-based alloys, such as e.g. Nd, Sm, Eu, Gd, Tb, or Dy.

In a fourth example, the ferromagnetic and/or ferrimagnetic material can include nitrogen compounds such as Mn₄N.

The layer 10 has a thickness comprised between 0.1 nanometer (nm) and 200 nm.

By definition, the thickness is the distance between the two faces of the magnetic layer 10 along the direction perpendicular to the plane wherein the magnetic layer 10 mainly extends.

Preferentially, the thickness of the magnetic layer 10 is comprised between 0.1 nm and 20 nm.

The magnetic layer 10 has magnetic properties including magnetization.

The magnetization of said magnetic layer is the quantity of magnetic moment per unit volume. Magnetization is a vector, not necessarily uniform across the layer, i.e. the direction thereof is variable from one point of the magnetic layer to another. The direction of magnetization of the magnetic layer means the direction of magnetization at each point of the layer. A modification of the direction of magnetization of the layer can thus affect the whole layer or only a part of the layer.

The modifying device 12 is a modifying device 12 of at least one magnetic property of the magnetic layer 10.

In the example described, the modifying device 12 is suitable for modifying the direction of magnetization of the magnetic layer 10.

The detection device 12 comprises a ferroelectric layer 14, a current generator 16 and a modifying unit 18.

The ferroelectric layer 14 is arranged on or under the magnetic layer 10 so as to define a stack 19 including at least the magnetic layer 10 and the ferroelectric layer 14.

In the example shown in FIG. 1, the ferroelectric layer 14 is in contact with the magnetic layer 10.

The ferroelectric layer 14 consists of a single- or multi-layer including one or a plurality of materials providing ferroelectric properties to the resulting layer.

According to the example shown in FIG. 1, the ferroelectric layer 14 includes a material advantageously having a perovskite structure.

E.g., the ferroelectric layer 14 includes BaTiO₃, PZT, PMN-PT, BiFeO₃, or SrTiO₃, or another ABO₃ element where A and B are two cations, or a mixture of such materials.

The acronym PZT denotes the element PbZr₁₋ₓTiₓO3 where x can vary between 0 and 1.

If appropriate, elements such as BiFeO₃ or SrTiO₃ can be doped. BiFeO₃ e.g. can be doped with rare earths.

In a variant, ferroelectric materials not having a perovskite structure can be envisaged. In particular, polyvinylidene fluoride (PVDF) or CsBiNb₂O₇ or the element (HF₁₋ₓZRₓ)O₂ or (HF₁₋ₓGAₓ)O₂ (where x varies between 0 and 1) can be mentioned.

In a variant, two-dimensional ferroelectric materials such as transition-metal dichalcogenides, such as WTE₂ or MOS₂ or MoSe₂, or CuInP₂S₆ can be used.

In a variant, Rashba ferroelectric semiconductor materials such as e.g. GeTe or GE₁₋ₓMnₓTe (where X varies between 0 and 1), doped or substituted, if appropriate, with Sn, or AgBiP₂X₆ (X=S, Se and Te), or LiZnSb, LiGaGe, KMgSb, LiBeBi, NaZnSb, LiCaBi can be used.

In a variant, the material can be a material which is not spontaneously ferroelectric but which can become ferroelectric by applying a stress, or an electric field, or by doping.

The ferroelectric layer 14 has a ferroelectric polarization.

The ferroelectric layer 14 has a thickness suitable for inverting the polarization thereof. As an indication, in the field of microelectronics for which the compatible voltages are generally less than 10 volts, typically a thickness of less than 100 nm and advantageously less than 50 nm, is an appropriate thickness.

In the example shown in FIG. 1, it is the modifying unit 18 which is apt to modify the ferroelectric polarization of the ferroelectric layer 14.

According to the example proposed, the modifying unit 18 is a voltage source, the variation of the voltage making it possible to modify the polarization.

An example of a voltage source is a voltage generator feeding the ferroelectric layer 14. The voltage generator is then connected to the stack 19 by contacts arranged e.g. on both sides of the stack 19.

According to another example of a voltage source, the latter is a transistor or a set of transistors produced e.g. by integrated circuits and electrically connected to the ferroelectric layer 14.

Furthermore, the current generator 16 is suitable for injecting current into the stack 19 along a direction parallel to the plane of the layers of the stack 19.

The plane of the layers of the stack 19 is a plane wherein the layers of the stack 19 extend.

The modifying unit 18 is thereby apt to modify the ferroelectric polarization of the ferroelectric layer 14, for modifying, with the generator 16, the direction of magnetization of the magnetic layer 10.

Indeed, the direction of magnetization of the magnetic layer 10 is related to the ferroelectric polarization of the ferroelectric layer 14 and to the electric current flowing through the stack 19.

Otherwise formulated, the polarization of the ferroelectric layer 14 and the application of a current through the stack 19 are used together for controlling the direction of magnetization of the magnetic layer 10.

The above implies that the ferroelectric layer 14 is spatially arranged with respect to the magnetic layer in order to modify the direction of magnetization of the latter under the effect of the current injected by the current generator 16.

More precisely, in operation, the modifying device 12 converts the charge motion (charging current) coming from the current injected by the current generator 16, into a spin magnetic moment flux (spin current) in the magnetic layer.

Such a current conversion from charging current to spin current is e.g. obtained by the Rashba-Edelstein effect. IN THE ORIGINAL, “conversation” should be “conversion”

The Rashba-Edelstein effect allows the charging current to be converted into a spin current at the surface of a topological insulator or at an interface or within the volume of certain materials. Same occurs when the inversion symmetry is broken, which results in the onset of an electric field perpendicular to the plane of the stack 19. Such is e.g., possibly, the case of the interface between the magnetic layer 10 and the ferroelectric layer 14.

In the presence of a Rashba-Edelstein effect, the electron wave vector and the spin are coupled; spin degeneration is lifted and, in the simplest case, the electronic structure of the surface or of the interface consists of two concentric Fermi contours with opposite spin chiralities.

When a charging current is injected by the current generator 16 into the stack 19, an opposite but non-equivalent shift of the Fermi contours occurs due to the Rashba-Edelstein effect, which generates a spin current.

Since the amplitude of the Rashba-Edelstein effect depends on the direction of polarization of the ferroelectric layer 14, the aforementioned conversion also depends on same, so that the spin current and hence the direction of magnetization also depend on same.

Controlling the state of polarization of the ferroelectric layer 14 thus makes it possible to control the properties of the spin current flowing through the magnetic layer 10 after injection of a charging current and thereby to modify the direction of magnetization.

In a variant, if the stack 19 includes a spin Hall effect material, the conversion of charging current into spin current can be obtained by the spin Hall effect and there again, the polarization of the ferroelectric layer 14 makes it possible to control the amplitude of the conversion by the spin Hall effect and hence the magnetization of the magnetic layer 10.

In all cases, a current applied through the stack 19 creates an accumulation of spin, the spins being in the plane of the stack 19, and orthogonal to the applied current. The diffusion of the spins in the adjacent magnetic layer 10 corresponds to a spin current, which generates a torque acting on the magnetization, making it possible to modify the direction of the magnetization. The amplitude and the sign of the spin current is controlled by the ferroelectric polarization of the ferroelectric layer 14.

In all cases, the modifying device 12 is thereby apt to implement a method of modifying the direction of magnetization of the magnetic layer 10.

The method includes a step of modifying the magnetization of the magnetic layer 10 by modifying the ferroelectric polarization of the ferroelectric layer 14 and by injecting an electric current into the stack 19 along a direction parallel to the plane of the layers of the stack 19.

In the case shown in FIG. 1, the modification of the ferroelectric polarization is implemented by applying an electric voltage to the ferroelectric layer 14.

The modifying unit 18 can thus be used for controlling the direction of magnetization of the magnetic layer 10 provided that a charging current is injected into the stack 19.

The additional degree of freedom provided by the voltage makes it possible to envisage using the modifying device 12 in a spintronic system so that the magnetic layer 10 can provide, in combination with other elements, supplementary functions such as memorization or re-programmability.

The modifying device 12 is thereby particularly advantageous in a spintronic system 30 as shown in FIG. 2.

The spintronic system 30 comprises the magnetic layer 10, the modifying device 12 shown in FIG. 1 and a unit 32 for reading the magnetization of the magnetic layer 10.

The unit 32 for reading the magnetization of the magnetic layer 10 is suitable for determining the direction of magnetization of the magnetic layer 10.

According to the example shown in FIG. 2, the reading unit 32 is a magnetic tunnel junction.

A magnetic tunnel junction is a stack of a magnetic layer separated from a free layer by a barrier layer. The free layer is the layer which can be switched under the effect of the spin-orbit torque. The barrier layer is e.g. made of MgO or of Al₂O₃.

In certain cases, as can be seen in FIG. 3, the reading unit 32 is positioned above the stack 19.

According to a variant, the reading unit 32 is positioned below the stack 19.

Other embodiments are possible for the reading unit 32. In particular, the reading unit 32 can be a stack with giant magnetoresistance layers, an extraordinary Hall effect reading unit within the magnetic layer 10, a planar Hall effect reading unit, or an anisotropic magnetoresistance reading unit.

In each case, the reading unit 32 is used for obtaining information which is encoded in the magnetic properties of the magnetic layer 10.

E.g., when the spintronic system 30 is a memory, the information is encoded along the direction of magnetization of the magnetic layer 10.

The memory works as a so-called spin-orbit torque magnetic memory, wherein the state of magnetization depends on the sign of the current pulse sent into the plane of the stack. In the example described, the state of magnetization written in the magnetic layer 10 further depends on the state of polarization of the ferroelectric layer 14, which can change the sign and the amplitude of the torque acting on the magnetization.

E.g., if the state of magnetization is described by 0 or 1, such values corresponding to opposite magnetizations, it is possible to switch from state 0 to state 1 by applying a current in the positive plane, if the polarization is positive. It is also possible to switch from 0 to 1 by applying a current in the negative plane, if the polarization is negative. It is in this way possible to use currents which are always positive for writing the information, by changing the ferroelectric polarization state, so as to control the magnetization state stored in memory.

It is not necessarily needed to constantly apply a voltage between the faces of the ferroelectric layer 14, since the ferroelectric polarization can be remanent.

In other embodiments, the information is encoded in the positions or the configurations of magnetic inhomogeneities such as walls of magnetic domains, skyrmions or spin waves propagating through the magnetic layer 10.

In such a case, modifying the ferroelectric polarization can be used for modifying the propagation of one of the aforementioned elements (wall/skyrmion/spin wave). The modification can be a modification of the speed (acceleration or deceleration, or even a change of sign or a stop) or of the amplitude (amplification or attenuation). For walls, skyrmions or spin waves moving in a circuit under the effect of spin-orbit torques, the control of the polarization at certain points of the circuit makes it possible to locally control the spin-orbit torque, and thus the movement and behavior of walls, skyrmions or spin waves. The use of ferroelectric polarization remanence can be used for reconfiguring such devices.

In such an application, the control device 12 thus provides an additional degree of freedom resulting in an improvement in the function performed by the control device 12.

Such an addition is advantageous for multiple spintronic systems 30, amongst which a memory, a shift register, a part of a logic or neuromorphic device, an oscillator, a radio frequency transmitter or a radio frequency receiver.

In some of the embodiments, the spintronic system (30) is a spin-transfer spin-orbit oscillator, the torque acting on the magnetization leading to the oscillation of the magnetization at frequencies on the order of the GHz, thereby generating a microwave signal for wireless communication.

Unlike conventional oscillators, for which the amplitude, the phase and the frequency of the signal depend only on the applied current, herein same also depend on the ferroelectric polarization of the ferroelectric element 14, which can thereby be adjusted in a remanent way. The above can e.g. be used for synchronizing oscillators with one another, for telecommunications or logic and/or neuromorphic applications.

On the other hand, it is possible to use such type of device as a receiver, the reception of a microwave signal initiating the oscillation of the magnetization of the magnetic layer 10, thereby generating a DC voltage in the plane of the stack. In such case, unlike in the case of memory devices, the control device 12 does not apply any current in the plane of the stack, but only measures the DC voltage generated in the plane of the stack by the oscillation of the magnetization.

In order to improve the properties of such spintronic systems 30, other embodiments of the modifying device 12 can be envisaged.

Thereby, another modifying device 12 is shown in FIG. 4.

The modifying device 12 shown in FIG. 4 has the same elements as the modifying device 12 shown in FIG. 1. Also, the common elements are not repeated hereinafter. Only the differences are presented hereinafter.

In the case of FIG. 4, the modifying device 12 further includes an intermediate layer 34 interposed between the magnetic layer 10 and the ferroelectric layer 14.

The intermediate layer 34 can be made of multiple materials.

E.g., the intermediate layer 34 is made of a spin-orbit material and has a thickness of less than 50 nm and advantageously less than 10 nm.

A spin-orbit material is a material for converting a charging current into a spin current.

In such a case, the spin-orbit material is advantageously one of the following: beta-tantalum (beta-Ta), BiSb, Ta, beta-tungsten (beta-W), W, Pt and Cu or Au doped with elements from the columns 3d, 4d, 5d, 4f, 5f of Mendeleev's table, such as W, Ta or Bi.

According to another example, the intermediate layer 34 can include a two-dimensional material, doped if appropriate, alone or in combination with other materials.

Graphene, NiSe₂, BiS, TiS, NiPS₃, WS₂, MoS₂, TiSe₂, VSe₂, MoSe₂, B₂S₃, Sb₂S, LaCPS₂, LaOAsS₂, ScOBiS₂, FePS₃, GaOBiS₂, AlOB, S₂, LaOSbS₂, BiOBiS₂, LaOBiSe₂, TiOBiS₂, CeOBiS₂, PrOBiS₂, NdOBiS₂, LaOBiS₂, CrGeTe₃, CrSiTe₃ or SrFBiS₂ are examples of two-dimensional materials.

In a variant, the intermediate layer 34 can include a Weyl semimetal alone or in combination with other materials.

TAS, TaP, NbAs, NbP, Na₃Bi, CD₃As₂, WTe₂ and MoTe₂ are examples of Weyl semimetals which can be used in the intermediate layer 34.

According to another example, the intermediate layer 34 includes a topological insulator. A topological insulator is a material with an insulating strip structure and which has metallic surface states.

Bi₂SE₃, BiseₓTe₂₋ₓ (x being comprised between 0 and 2), BiSbTe, SbTe₃ and HgTe are examples of topological insulators which can be used in the intermediate layer 34.

In a variant, the intermediate layer 34 can include a transition-metal dichalcogenide.

Preferentially, in such a case, the material of the intermediate layer 34 is a material having a chemical formula which writes as ROCh₂ wherein the element R is chosen from the list consisting of La, CE, Pr, Nd, Sr, Sr, Gr, Al and In, and the Ch element is selected from the list consisting of S, Se and Te.

Such types of materials exhibit a spin-orbit effect satisfactory for the intermediate layer 34.

In summary, the material of the intermediate layer 34 is advantageously a spin-orbit material and in particular a Weyl semimetal and/or a topological insulator and/or a two-dimensional material and/or a transition-metal dichalcogenide and/or an oxide (e.g. LaAlO₃) and/or further a metal such as platinum or tungsten.

The operation of the modifying device 12 according to FIG. 4 is similar to the operation described for the modifying device 12 according to FIG. 1.

Other further embodiments are possible.

E.g., the ferroelectric layer 14 is in contact with a protective layer.

The protective layer makes it possible to create and/or protect an electron gas being formed on the surface of the ferroelectric layer 14.

The protective layer is a layer comprising at least 80%, in atom proportion, of a metal element of the columns 3d, 4d, 5d, 4f, 5f of the periodic table such as Al, Ta, Ru, IR, Mo, TI, Y, Au, or a combination of said elements, such as AlTa. Such protective layer will partially or totally oxidize, creating oxygen vacancies in the ferroelectric element 14 and thereby generating a two-dimensional electron gas at the interface between the metallic element, having a carrier density greater than 10¹⁰ cm⁻².

In a particular case, the protective layer is made of Ru, Al, Ta, Ti, Mg or Y.

According to another embodiment or in addition, the magnetic layer 10 is nanostructu red.

Such a nanostructure can in particular be achieved by using a lithography technique.

In this way it is possible to obtain e.g. a set of nano-elements having one dimension or dimensions, in the plane of the stack, of less than 100 nm. Such a configuration is advantageous for the case of memories or parts of neuromorphic devices.

According to another example, in this way it is possible to produce nano-tracks, in particular tracks with a width of less than 200 nm, suitable for the case of devices based on the use of domain walls or of skyrmions.

In some applications, in a variant or in addition, the ferroelectric layer 14 is nanostructured.

A person skilled in the art will understand that the modifying device 12 can include any combination of the aforementioned embodiments.

In each case, the modifying device 12 can be used for modifying at least one magnetic property of a magnetic layer (herein, the direction of magnetization) which provides more degrees of freedom for a spintronic system 30 which would comprise such a modifying device 12.

1. A device for modifying at least the direction of magnetization of a magnetic layer, the modifying device including:
a ferroelectric layer having a ferroelectric polarization, arranged on or under the magnetic layer so as to define a stack including at least the magnetic layer and the ferroelectric layer, a plane wherein the layers of the stack extend being defined,
a generator apt to inject an electric current into the stack along a direction parallel to the plane of the layers of the stack, and
a modification unit adapted to modify the ferroelectric polarization of the ferroelectric layer, for modifying, with the generator, the direction of magnetization of the magnetic layer.

2. The modifying device according to claim 1, wherein the unit for modifying the ferroelectric polarization is a voltage source.

3. The modifying device according to claim 1, wherein the magnetic layer is in contact with the ferroelectric layer.

4. The modifying device according to claim 1, wherein at least one amongst the magnetic layer and the ferroelectric layer is nanostructured.

5. The modifying device according to claim 1, wherein the stack includes an intermediate layer interposed between the ferroelectric layer and the magnetic layer, the intermediate layer including a spin Hall effect material.

6. The modifying device according to claim 1, wherein the stack includes an intermediate layer interposed between the ferroelectric layer and the magnetic layer, the intermediate layer including a material selected from the following list, taken alone or in combination:
a Weyl semimetal,
a two-dimensional material, in particular graphene,
a transition-metal dichalcogenide, and
a topological insulator.

7. The modifying device according to claim 1, wherein the ferroelectric layer is in contact with a protective layer.

8. The modifying device according to claim 7, wherein the protective layer can be used for protecting a two-dimensional electron gas being formed on the surface of the ferroelectric layer.

9. The modifying device according to claim 7, wherein the protective layer is obtained by depositing at least 80% of a reducing metal element from the columns 3d, 4d, 5d, 4f, 5f of the periodic table, or a combination of said elements.

10. A spintronic system comprising:
a magnetic layer,
a device for modifying at least the direction of magnetization of the magnetic layer, the modifying device being according to claim 1, and
a unit for reading the magnetization of the magnetic layer.

11. The spintronic system according to claim 10, wherein the spintronic system is a memory.

12. The spintronic system according to claim 10, wherein the spintronic system is a shift register based on propagation of magnetic domain walls or of skyrmions.

13. The spintronic system according to claim 10, wherein the spintronic system is part of a logic or neuromorphic device based on the propagation of magnetic domain walls or of skyrmions or of spin waves.

14. The spintronic system according to claim 10, wherein the spintronic system is selected from:
an oscillator, and
a radio frequency transmitter or receiver.

15. A method for modifying at least the direction of magnetization of a magnetic layer, the method including:
a step of modifying the magnetization of the magnetic layer by the modification of the ferroelectric polarization of a ferroelectric layer arranged on or under the magnetic layer so as to define a stack including at least the magnetic layer and the ferroelectric layer, a plane wherein the layers of the stack extend being defined, and by the injection of an electric current into the stack along a direction parallel to the plane of the layers of the stack.
